(19) United States
(12) Patent Application Publication
(10) Pub. No.: US 2021/0028375 A1
(43) Pub. Date: Jan. 28, 2021

(54) NANOPARTICLE ARCHITECTURES AND METHODS OF PREPARATION THEREOF

(71) Applicant: YISSUM RESEARCH DEVELOPMENT COMPANY OF THE HEBREW UNIVERSITY OF JERUSALEM LTD, Jerusalem (IL)

(72) Inventors: Uri Banin, Mevasseret Zion (IL); Botao Ji, Jerusalem (IL); Nir Waiskopf, Jerusalem (IL)

(21) Appl. No.: 17/042,330

(22) PCT Filed: Jun. 3, 2019
(86) PCT No.: PCT/IL2019/050630

§ 371 Date: Sep. 28, 2020

Related U.S. Application Data
(60) Provisional application No. 62/679,990, filed on Jun. 4, 2018.

(51) Int. Cl. H01L 51/00; C09K 11/56

(52) U.S. Cl. CPC H01L 51/0092; B82Y 30/00; C09K 11/565

(57) ABSTRACT

The invention disclosed herein provides a novel class of surface-decorated nanometric particles, and uses thereof.

### TECHNOLOGICAL FIELD

The invention generally concerns novel core/shell materials wherein the shell structure is in the form a wetting layer and surface-dispersed islands. The invention further contemplates uses thereof.

### BACKGROUND

Semiconductor nanorods exhibit and offer advantages, such as large absorption cross section, allowing higher photosensitivity and better intrinsic charge separation in comparison to quantum dots. Moreover, such systems are well suited for applications requiring use of small colloidal systems.

The Stranski-Krastanov (SK) type growth is a typical method for epitaxial film growth on a flat substrate which leads to the formation of continuous layer with islands on its surface, so called layer-plus-islands growth behavior. In SK growth, when a different material is grown on a two-dimensional substrate, a complete film (wetting layer) is first formed (up to several monolayers). The lattice mismatch among the two materials induces strain energy which increases with the layer thickness. Above a critical thickness, three-dimensional islands begin to form to relieve the misfit strain energy. As the lattice mismatch is larger, the thinner will be the wetting layer until a point in which a wetting layer is no more favorable and a different growth mechanism of islands becomes possible [1].

Kuno et al. reported islands growth on colloidal semiconductor nanowires [2]. The nanowires with lengths of several micrometers were synthesized through a solution-liquid-solid (SLS) growth, where metallic nanoparticles were used as the catalysts. It was shown that the shell growth of CdS on CdSe nanowires favored the wetting layer and followed the layer-plus-island growth behavior. In contrast, the shell growth of CdSe on CdS nanowires favored anti-wetting, resulting in direct islands growth without wetting layers.

Mews et al. showed that at high temperature nanowires were not stable in solvents, such as trioctylphosphine, trioctylphosphine oxide, octadecene and oleylamine, especially when the temperature was higher than 200° C. [3]. This was manifested in the loss of the original dimensions due to significant shortening of the nanowires.

SK growth on spherical quantum dots was also suggested [4]. However, one of the key parameters for SK growth, the total strain energy in the interface of the two semiconductors resulting from the lattice mismatch, is significantly different between quantum dots and nanoscale colloidal anisotropic nanostructures, such as nanorods. This leads to different requirements for shell growth on these systems [4], limiting direct transfer of knowledge from one system to the other.

### BACKGROUND ART

[1] Stranski, Ivan N.; Krastanow, Lubomir (1938). “Zur Theorie der orientierten Ausscheidung von Ionenkristallen aufeinander”. Abhandlungen der Mathematisch-Naturwissenschaftlichen Klasse IIb. Akademie der Wissenschaften Wien. 146: 797-810;

[2] Goebl, J. A.; Black, R. W.; Puthussery, J.; Giblin, J.; Kosel, T. H.; Kuno, M. Solution-Based II-VI Core/Shell Nanowire Heterostructures. J. Am. Chem. Soc. 2008, 130, 14822-14833.

[3] Li, Z.; Ma, X.; Sun, Q.; Wang, Z.; Liu, J.; Zhu, Z.; Qiao, S. Z.; Smith, S. C.; Lu, G. (Max); Mews, A. Synthesis and Characterization of Colloidal Core-Shell Semiconductor Nanowires. Eur. J. Inorg. Chem. 2010, 4325-4331.

[4] Jiang, Z. J.; Kelly, D. F. Stranski-Krastanov Shell Growth in ZnTe/CdSe Core/Shell Nanocrystals. J. Phys. Chem. C 2013,117 (13), 6826-6834.

[5] Manna, L.; Scher, E. C.; Li, L. S.; Alivisatos, A. P. Epitaxial Growth and Photochemical Annealing of Graded CdS/ZnS Shells on Colloidal CdSe Nanorods. J. Am. Chem. Soc., 2002,124 (24), 7136-7145.

### GENERAL DESCRIPTION

The ability to achieve islands in the form of Stranski-Krastanov (SK) growths on nanostructures is not straightforward, since such SK growths reside in a delicate intermediate regime between continuous shell growth and direct formation of islands without a wetting layer when the lattice mismatch is too large.

The observation of nanowire shortening, which can be even more crucial when working with nanorods, having already limited lengths, adds to the complexity of the SK growth procedure, as previously described for nanowires. This is supported by experiments conducted by the inventors, which exemplify the complexity of SK growth on nanoparticles with nanometric three-dimensional sizes.

In the inventors' early experiments, growth of CdS shell on CdSe nanorods and growth of CdS shell on ZnS nanorods (FIG. 1) resulted in no island growth. The failure to achieve SK growth on nanorods may be attributed to the structural differences between nanowires and nanorods. Despite numerous attempts, growth of islands on nanorods according to the SK procedure has not been successfully achieved, attesting to the fact that the transfer from SK growth on nanowires to SK growth on nanorods is not straightforward. This is also due to the fact that SK growth is driven by thermodynamic growth conditions, rather than kinetic conditions. The conditions for thermodynamic growth would then imply a tendency of nanorods to ripen towards the thermodynamically stable spherical nanocrystal shapes. This seemingly unsolved competition and balance between SK growth versus ripening has been resolved in the present invention allowing for the epitaxial SK type growth.

The inventors of the technology disclosed herein have now developed a novel family of nanometric particles, i.e., nanoparticles being nanometric throughout, namely on all dimensions, such as nanorods/shells structures, manifesting SK growth on the nanorod cores. As will be further demonstrated herein below, in the synthesis of an exemplary system such as ZnSe/ZnS core/shell nanorods, the uniform deposition of several monolayers of ZnS on the surface of the ZnSe nanorod core accumulates lattice strain. As the thickness of the ZnS shell exceeds a critical thickness, the balance between strain energy and surface energy is reversed and therefore leads to growth of three-dimensional islands. The generality of such on colloidal nanorods structures may be further demonstrated via the similar growth manner of ZnS shell on other nanorods including CdSe/CdS seeded nanorods and CdSe nanorods. In this process, the lattice mismatch plays a key role in determining the critical thickness. The islands growth during shell deposition can be extended to different materials (ZnSe) and morphologies (two-dimensional nanoplates).

The unique core/islands-shell architecture of the colloidal semiconductor nanostructures commences with the formation of a wetting layer followed by growth of material islands. Under suitable shell growth conditions and system tailoring, this can also result in core/helical-islands shell. These unique architectures allow benefiting from the increased surface area, good passivation layer (mainly in its thicker regions) and enhanced electrical coupling to the inner semiconductor where the shell layer is thin.

The growth mechanism involves a Stranski-Krastanov (SK) growth mode—the so-called layer-plus-islands growth behavior. In the SK growth, when a different material is grown on a two-dimensional substrate, a complete film (wetting layer) is first formed (up to several monolayers) on the outer-most layer of the substrate (circumference). The lattice mismatch among the two materials induces strain energy which increases with the layer thickness. Above a critical thickness, three-dimensional islands begin to form to relieve the misfit strain energy. As lattice mismatch increases, continued growth of the wetting layer becomes unfavorable or less favorable and a growth mechanism leading to the formation of islands becomes possible.

In a first aspect, the invention provides a nanostructure of a first semiconductor material, coated on its circumference with a layer of a second semiconductor material (a wetting layer), said layer of a second semiconductor material being decorated with a plurality (one or more) of material islands of the same second semiconductor material. The first and second semiconductor materials are different.

As defined herein, the nanostructures of the invention are those characterized by any shape and having each and every axis thereof in the nanoscale. The nanostructures of the invention are not nanowires or quantum dots. In other words, the term “nanostructure” as defined herein excludes nanowires and quantum dots.

The nanostructure circumference is the outer surface of the nanostructure. The layer of the second semiconductor material which forms on the nanostructure top-most surface, circumference, typically fully or substantially completely coats or covers this outer surface.

In some embodiments, the layer of the second semiconductor material is a SK growth layer (or multilayer or shell). In other words, the layer of the second semiconductor material is a layer-plus-island that is formed by deposition of the second semiconductor material as a wetting layer of one to several monolayers on the circumference of the first semiconductor material. Presence of a lattice mismatch between the first and second semiconductor materials induces strain energy and subsequently causes formation of islands on the layer of the second semiconductor material.

In some embodiments, the layer of the second semiconductor material comprises one or more monolayers of said second semiconductor material.

In some embodiments, the material islands are orderly arranged or randomly arranged. In some embodiments, the material islands are orderly arranged. In some embodiments, the growth is an ordered SK growth.

In some embodiments, the islands are arranged in a line form, optionally helically arranged on the circumference of the nanostructure.

The invention further provides an anisotropic nanostructure of a first semiconductor material, coated on its circumference (outer skin) with a Stranski-Krastanov (SK) wetting layer of a second semiconductor material (the shell having a layer-plus-island form). In some embodiments, the wetting layer comprises material islands of the second semiconductor material.

In some embodiments, the nanostructure is of a first semiconductor material, coated with a film comprised of one or more monolayers of a second semiconductor material, the film being characterized by regions of accumulated lattice strain, said regions exhibit three-dimensional islands of the second semiconductor material, wherein the first and second semiconductor materials are different.

The invention further provides a nanostructure of a first semiconductor material, coated with a film comprised of one or more monolayers of a second semiconductor material, the film being characterized by regions of accumulated lattice strain, said regions exhibiting three-dimensional islands of the second semiconductor material, wherein the nanostructure having each of its dimensions in the nanoscale and excluding nanowires and quantum dots.

“Nanostructures” of the invention are nanoparticles characterized by having each and every one of their dimensions in the nanoscale. The nanostructure may be selected from nanorods, nanotubes, nanoparticles, nanoplates or any other regularly or irregularly shaped nanostructures (including V-shaped structures, tripods, tetrapods, square-shaped structures, cages etc). Where the nanostructure is an elongated structure, its diameter (thickness) as well as its length is nanometric. Where the nanostructure is a nanoplate, the diameter and thickness of the nanoplate are both in the nanoscale. Any nanoparticle that is irregularly shaped has each any every of its dimensions in the nanoscale.

As used herein, “nanometric” or “nanoscale” refers to dimensions between 1 nm and 1,000 nm, excluding 1,000 nm. In some embodiments, the nanometric dimensions are below 1 micron. In some embodiments, the nanometric dimensions are between 1 and 100 nm, 1 and 90 nm, 1 and 80 nm, 1 and 70 nm, 1 and 60 nm, 1 and 50 nm, 1 and 40 nm, 1 and 30 nm, 1 and 20 nm, 1 and 10 nm, 10 and 100 nm, 15 and 100 nm, 20 and 100 nm, 25 and 100 nm, 30 and 100 nm, 35 and 100 nm, 40 and 100 nm, 45 and 100 nm, 50 and 100 nm, 55 and 100 nm, 60 and 100 nm, 65 and 100 nm, 70 and 100 nm, 75 and 100 nm, 80 and 100 nm, 85 and 100 nm, 90 and 100 nm, 95 and 100 nm, 100 and 900 nm, 100 and 850 nm, 100 and 800 nm, 100 and 750 nm, 100 and 700 nm, 100 and 650 nm, 100 and 600 nm, 100 and 550 nm, 100 and 500 nm, 100 and 450 nm, 100 and 400 nm, 100 and 350 nm, 100 and 300 nm, 100 and 250 nm, 100 and 200 nm or 100 and 150 nm.

In some embodiments, the dimensions are between 1 and 20 nm, 1 and 19 nm, 1 and 18 nm, 1 and 17 nm, 1 and 16 nm, 1 and 15 nm, 1 and 14 nm, 1 and 13 nm, 1 and 12 nm, 1 and 11 nm, 1 and 10 nm, 1 and 9 nm, 1 and 8 nm, 1 and 7 nm, 1 and 6 nm, 1 and 5 nm or between 1 and 4 nm.

Notwithstanding the structure or shape or size of the nanostructure, it may be selected amongst core/shell structures and may or may not be doped. The nanostructure, notwithstanding its structure, shape and size has a top-most surface, or an exposed outer boundary, or an outer skin, or a circumference that is coated with a second semiconductor material, as defined herein.

In some embodiments, the nanostructure is a nanorod, a nanoplate or a nanoparticle which may be in the form of a core/shell or may be doped. The nanostructure is constructed of at least one material, such that in case the nanostructure is not a core/shell structure nor doped, it is of semiconductor material as defined. Where the nanostructure is a core/shell structure, it may have at least one core material and depending on the number of shells (core/shell or core/multi-shell), may have shells of different semiconductor materials. Where the nanostructure is a doped particle, it may be composed of at least one semiconductor material that is further doped, as known in the art.

The first semiconductor material, form which the nanostructures are composed, may be two or more such materials depending on the structure of the nanostructure. In one example, the nanostructure is a nanorod composed of a single semiconductor material.

In another example, the nanostructure is a core/shell structure having a core of one semiconductor material and an outer shell(s) of a different semiconductor material(s). In case of a core/shell structure, the shell material, being of a material different from the core material, is not the herein referred to second semiconductor material. The core/shell nanostructure comprises a coating of an SK shell/growth of a semiconductor material that is different from the shell material of the core/shell nanostructure.

In other embodiments, the nanostructure is a seeded nanostructure, e.g., a seeded nanorod. The first semiconductor material and the material from which the wetting layer and the islands, i.e., the second semiconductor material, are formed, are different. Both materials may be selected from the same class(es) of semiconductor materials, but are nevertheless different.

Thus, such nanostructures may be regarded as being fully structured of semiconductor materials (consisting semiconductor materials).

The material of the nanostructure and the material of the wetting layer and islands material may be selected on the basis of their structural and electronic properties. In some embodiments, each of the materials, independently of the other material, is a semiconductor material or an oxide, a ternary semiconductor form, a quaternary semiconductor form, an alloy (or a combination thereof), being selected from elements of Group I-VII, Group II-VI, Group III-V, Group IV-VI, Group III-VI, Group IV semiconductors, Group III-VI semiconductors, Group I-VI semiconductors, I-VII semiconductors, IV-VI semiconductors, V-VI semiconductors, II-V semiconductors and I-III-VI₂ semiconductors.

In some embodiments, the semiconductor material is a Group I-VII semiconductor selected from CuF, CuCl, CuBr, CuI, AgCl, AgBr, AgI and the like.

In some embodiments, the semiconductor material is a Group II-VI material selected from CdSe, CdS, CdTe, ZnSe, ZnS, ZnTe, HgS, HgSe, HgTe, CdZnSe, CdSeTe, ZnO and any combination thereof.

In some embodiments, the semiconductor material is a Group III-V material selected from InAs, InP, InN, GaN, InSb, InAsP, InGaAs, GaAs, GaP, GaSb, AlP, AlN, AlAs, AlSb and any combination thereof.

In some embodiments, the semiconductor material is a Group IV-VI material selected from PbSe, PbTe, PbS, PbSnTe, Tl₂SnTe₅ and any combination thereof.

In some embodiments, the material is or comprises an element of Group IV. In some embodiments, the material is selected from C, Si, Ge, Sn and Pb.

In some embodiments, the material is selected from Cu₂S, Cu₂Se, CuInS₂, CuInSe₂, Cu₂(ZnSn)S₄, Cu₂(InGa)S₄, CuInS₂, CuGaS₂, CuAlS₂ and mixed copper-iron sulfides such as Cu₅FeS₄ (Bornite) and CuFeS₂ (chalcopyrite).

In some embodiments, the material is or comprises a semiconductor material.

In some embodiments, in the materials are selected from InAs, InP, CdSe, CdS, CdZnS, ZnTe, ZnS, ZnSe, ZnTe/ZnS and ZnSeTe.

In some embodiments, the core/island-shell nanostructure is selected from ZnSe/ZnS, ZnSe/ZnS/ZnO, ZnSe/ZnS/CdS, CdS/ZnS, CdS/ZnS/CdS, CdSe/CdS/ZnS, CdSe/CdS/ZnS/CdS, CdSe/ZnS, CdSe/ZnS/CdS, ZnS/ZnSe, ZnS/ZnSe/CdS, CdS/ZnSe, CdS/ZnSe/CdS, CdSe/ZnSe and CdSe/ZnSe/CdS.

In some embodiments, the core/island-shell nanostructure is selected from an alloy of the above mentioned materials. In some embodiments, the core/island-shell nanostructure comprises a Zn-based semiconductor material.

The wetting layer and islands formed on the circumference of the nanostructure are of a single semiconductor material. The wetting layer comprises one or more monolayers of the second semiconductor. The number of monolayers may vary from 1 to about 10. In some embodiments, the number of monolayers varies between 2 and 10. In other embodiments, the one or more monolayers form a shell of a thickness ranging from 0.1 nm to about 6 nm

As mentioned in the background, the uniform deposition of several monolayers of the semiconductor material on the surface of the nanostructure, e.g., nanorod, induces lattice strain because of the lattice mismatch. Further increase of the thickness of the coating layer increases the interfacial strain energy until a critical thickness is achieved in the accumulated strain leads to the formation of three-dimensional islands. These islands are generally distributed along the surface of the wetting layer in a random distribution profile or a patterned profile.

The features of the resulting nanostructure depend on properties of the composing materials along with the synthesis parameters. For example, (1) the electronic properties of the nanostructures may depend on the energy band alignments; (2) the thickness of the wetting layer may change from one monolayer to several layers depending the lattice mismatch between the materials, and (3) the average height or length of these islands can depend on the reaction time and availability of precursors.

With suitable shell growth conditions and system tailoring, unique nanostructures such as core/helical-islands shell nanostructures may be formed. Hence, in another aspect, the invention provides novel means to produce chiral nanostructures. The unique class of nanostructures of the invention is manufactured by colloidal growth of epitaxial shells on existing shell-free nanostructures, e.g., nanorods. As indicated herein, the so-called “core nanostructures” are nanostructures which are free of a wetting layer and islands (free of SK growths), or which have not undergone chemical modification according to the invention, namely have not been treated as disclosed herein to form a wetting film and islands of a second or different material. Note that in some embodiments, the core nanostructures may be themselves core/shell structures, where the shell growth in this case is one known in the art. Thus said core nanostructure may serve as basis for further growth of the nanostructures in accordance with the invention.

According to the invention, the process comprises contacting preformed bare nanostructures, namely core nanostructures with at least one shell precursor of low reactivity, slowly introduced at elevated temperatures.

In some embodiments, the process comprises adding at least one shell precursor material to a medium comprising preformed core nanostructures, at a rate and under thermal conditions permitting growth of a wetting layer and material islands on the surface of the core nanostructures.

In some embodiments, the at least one shell precursor is selected from a chalcogenide precursor, e.g., an alkyl thiol, and a metal precursor.

The chalcogenide precursor may be any organic precursor of a chalcogenide. The chalcogenide may be selected from Te, Se and S. In some embodiments, the chalcogenide precursor is an organic precursor, such as alkyl thiol, selected from alkyls having between 1 and 20 carbon atoms. In some embodiments, the alkyl is a C₁-C₂₀alkyl, C₁-C₁₉alkylC₁-C₁₈alkyl, C₁-C₁₇alkyl, C₁-C₁₆alkyl, C₁-C₁₅alkyl, C₁-C₁₄alkyl, C₁-C₁₃alkyl, C₁-C₁₂alkyl, C₁-C₁₁alkyl, C₁-C₁₀alkyl, C₁-C₉alkyl, C₁-C₈alkyl, C₁-C₇alkyl, C₁-C₆alkyl, C₁-C₅alkyl, C₁-C₄alkyl or Cₗ-C₃alkyl. In some embodiments, the alkyl thiol is octanethiol.

In some embodiments, the chalcogenide precursor is an organic precursor, such as a branched alkyl thiol.

In some embodiments, the chalcogenide precursor is an organic precursor, such as a ring thiol.

In some embodiments, the chalcogenide precursor is an organic precursor, such as a dithiol.

In some embodiments, the chalcogenide precursor is an organic precursor, such as a functional thiol.

In some embodiments, the chalcogenide precursor is an organic precursor, such as a protected thiol.

In some embodiments, the chalcogenide precursor is an organic precursor, such an amino acid comprising a sulfur atom.

The metal precursor may be selected from metal chlorides, metal chlorides hydrates, metal hypochlorites/chlorites/chlorates/cerchlorates, metal hypochlorites/chlorites/chlorates/perchlorates hydrates, metal carbonates, metal carbonate hydrates, metal carboxylates, metal carboxylates hydrates, metal oxides, metal acetates, metal acetates hydrates, metal acetylacetonates, metal acetylacetonate hydrates, metal nitrates, metal nitrates hydrates, metal nitrites, metal nitrites hydrates, metal cyanates, metal cyanates hydrates, metal sulfides, metal sulfides hydrates, metal sulfites, metal sulfites hydrates, metal hyposulfite, metal hyposulfite hydrates, metal sulfate, metal sulfate hydrates, metal thiosulfate, metal thiosulfate hydrates, metal dithionites, metal dithionites hydrates, metal phosphates, metal phosphates hydrates, metal alkyls, metal alkoxides, metal amines, metal phosphines, metal thiolates, metal halides, and combined cation-anion single source precursors.

These metal precursors may be any one or more of:
Metal precursors as cations, wherein “M” represents a metal atom such as Cd, Zn, In, Ga, Al and others, include:
chlorides, e.g., selected from MCl, MCl₂, MCl₃, MCl₄, MCl₅, and MCl₆;
chlorides hydrates, e.g., selected from MCl·xH₂O, MCl₂·H₂O, MCl₃·xH₂O, MCl₄·xH₂O, MCl₅·xH₂O, and MCl₆·xH₂O, wherein x varies based on the nature of M;
hypochlorites/chlorites/chlorates/cerchlorates (abbreviated ClOₙ⁻, n=1, 2, 3, 4), e.g., selected from MClOₙ, M(ClOₙ)₂, M(ClOₙ)₃, M(ClOₙ)₄, M(ClOₙ)₅, and M(ClOₙ)₆;
hypochlorites/chlorites/chlorates/perchlorates hydrates, e.g., selected from MClOₙ·xH₂O, M(ClOₙ)₂·xH₂O, M(ClOₙ)₃·xH₂O, M(ClOₙ)₄·xH₂O, M(ClOₙ)₅·xH₂O, and M(ClOₙ)₆·xH₂O, wherein x varies based on the nature of M, and n=1, 2, 3, 4;
carbonates, e.g., selected from M₂CO₃, MCO₃, M₂(CO₃)3, M(CO₃)₂, M₂(CO₃)₂, M(CO₃)₃, M₃(CO₃)₄, M(CO₃)₅, M₂(CO₃)₇;
carbonate hydrates, e.g., selected from M₂CO₃·xH₂O, MCO₃·xH₂O, M₂(CO₃)₃·xH₂O, M(CO₃)₂·xH₂O, M₂(CO₃)₂·xH₂O, M(CO₃)₃·xH₂O, M₃(CO₃)₄·xH₂O, M(CO₃)₅·xH₂O, and M₂(CO₃)₇·xH₂O, wherein x varies based on the nature of M;
carboxylates (abbreviated RCO₂, and including acetates), e.g., selected from MRCO₂, M(RCO₂)₂, M(RCO₂)₃, M(RCO₂)₄, M(RCO₂)₅, and M(RCO₂)₆;
carboxylates hydrates (abbreviated RCO₂⁻), e.g., selected from MRCO₂·xH₂O, M(RCO₂)₂·xH₂O, M(RCO₂)₃·xH₂O, M(RCO₂)₄·xH₂O, M(RCO₂)5·xH₂O, and M(RCO₂)₆·xH₂O, wherein x varies based on the nature of M;
carboxylate (the group RCOO⁻, R is aliphatic chain, which may be saturated or unsaturated), e.g., selected from CH₃CH═CHCOOM (metal crotonate), CH₃(CH₂)₃CH═CH(CH₂)₇COOM (metal myristoleate), CH₃(CH₂)₅CH═CH(CH₂)₇COOM (metal palmitoleate), CH₃(CH₂)₈CH═CH(CH₂)₄COOM (metal sapienate), CH₃(CH₂)₇CH═CH(CH₂)₇COOM (metal oleate), CH₃(CH₂)₇CH═CH(CH₂)₇COOM (metal elaidate), CH₃(CH₂)₅CH═CH(CH₂)₉COOM (metal vaccinate), CH₃(CH₂)₇CH═CH(CH₂)₁₁COOM (metal erucate), C₁₇H₃₅COOM (metal stearate);
oxides, e.g., selected from M₂O, MO, M₂O₃, MO₂, M₂O₂, MO₃, M₃O₄, MO₅, and M₂O₇;
acetates, e.g., (the group CH₃C00⁻, abbreviated AcO⁻) selected from AcOM, AcO₂M, AcO₃M, and AcO₄M;
acetates hydrates, (the group CH₃COO⁻, abbreviated AcO⁻), e.g., selected from AcOM·xH₂O, AcO₂M·xH₂O, AcO₃M·xH₂O, and AcO₄M·xH₂O, wherein x varies based on the nature of M;
acetylacetonates (the group C₂H₇CO₂⁻, abbreviated AcAc⁻), e.g., selected from AcAcM, AcAc₂M, AcAc₃M, and AcAc₄M;
acetylacetonate hydrates (the group C₂H₇CO₂⁻, abbreviated AcAc⁻), e.g., selected from AcAcM·xH₂O, AcAc₂M·xH₂O, AcAc₃M·xH₂O, and AcAc₄M·xH₂O, wherein x varies based on the nature of M;
nitrates, e.g., selected from MNO₃, M(NO₃)₂, M(NO₃)₃, M(NO₃)₄, M(NO₃)₅, and M(NO₃)₆;
nitrates hydrates, e.g., selected from MNO₃·xH₂O, M(NO₃)₂·xH₂O, M(NO₃)₃·xH₂O, M(NO₃)₄·xH₂O, M(NO₃)₅·xH₂O, and M(NO₃)₆·xH₂O, wherein x varies based on the nature of M;
nitrites, e.g., selected from MNO₂, M(NO₂)₂, M(NO₂)₃, M(NO₂)₄, M(NO₂)₅, and M(NO₂)₆;
nitrites hydrates, e.g., selected from MNO₂·xH₂O, M(NO₂)₂·xH₂O, M(NO₂)₃·xH₂O, M(NO₂)₄·xH₂O, M(NO₂)₅·xH₂O, and M(NO₂)₆·xH₂O, wherein x varies based on the nature of M;
cyanates, e.g., selected from MCN, M(CN)₂, M(CN)₃, M(CN)₄, M(CN)₅, M(CN)₆;
cyanates hydrates, e.g., selected from MCN·xH₂O, M(CN)₂·xH₂O, M(CN)₃·xH₂O, M(CN)₄·xH₂O, M(CN)₅·xH₂O, and M(CN)₆·xH₂O, wherein x varies based on the nature of M;
sulfides, e.g., selected from M₂S, MS, M₂S₃, MS₂, M₂S₂, MS₃, M₃S₄, MS₅, and M₂S₇;
sulfides hydrates, e.g., selected from M₂S·xH₂O, MS·xH₂O, M₂S₃·xH₂O, MS₂·xH₂O, M₂S₂·xH₂O, MS₃·xH₂O, M₃S₄·xH₂O, MS₅·xH₂O, and M₂S₇·xH₂O, wherein x varies based on the nature of M;
sulfites, e.g., selected from M₂SO₃, MSO₃, M₂(SO₃)₃, M(SO₃)₂, M₂(SO₃)₂, M(SO₃)₃, M₃(SO₃)₄, M(SO₃)₅, and M₂(SO₃)₇;
sulfites hydrates selected from M₂SO₃·xH₂O, MSO₃·xH₂O, M₂(SO₃)₃·xH₂O, M(SO₃)₂·xH₂O, M₂(SO₃)₂·xH₂O, M(SO₃)₃·xH₂O, M₃(SO₃)₄·xH₂O, M(SO₃)₅·xH₂O, and M₂(SO₃)₇·xH₂O, wherein x varies based on the nature of M;
hyposulfite, e.g., selected from M₂SO₂, MSO₂, M₂(SO₂)₃, M(SO₂)₂, M₂(SO₂)₂, M(SO₂)₃, M₃(SO₂)₄, M(SO₂)₅, and M₂(SO₂)₇;
hyposulfite hydrates, e.g., selected from M₂SO₂·xH₂O, MSO₂·xH₂O, M₂(SO₂)₃·xH₂O, M(SO₂)₂·xH₂O, M₂(SO₂)₂·xH₂O, M(SO₂)₃·xH₂O, M₃(SO₂)₄·xH₂O, M(SO₂)₅·xH₂O, and M₂(SO₂)₇·xH₂O, wherein x varies based on the nature of M;
sulfate, e.g., selected from M₂SO₃, MSO₃, M₂(SO₃)₃, M(SO₃)₂, M₂(SO₃)₂, M(SO₃)₃, M₃(SO₃)₄, M(SO₃)₅, and M₂(SO₃)₇;
sulfate hydrates, e.g., selected from M₂SO₃·xH₂O, MSO₃·xH₂O, M₂(SO₃)₃·xH₂O, M(SO₃)₂·xH₂O, M₂(SO₃)₂·xH₂O, M(SO₃)₃·xH₂O, M₃(SO₃)₄·xH₂O, M(SO₃)₅·xH₂O, and M₂(SO₃)₇·xH₂O, wherein x varies based on the nature of M;
thiosulfate, e.g., selected from M₂S₂O₃, MS₂O₃, M₂(S₂O₃)₃, M(S₂O₃)₂, M₂(S₂O₃)₂, M(S₂O₃)₃, M₃(S₂O₃)₄, M(S₂O₃)₅, and M₂(S₂O₃)₇;
thiosulfate hydrates, e.g., selected from M₂S₂O₃·xH₂O, MS₂O₃·xH₂O, M₂(S₂O₃)₃·xH₂O, M(S₂O₃)₂·xH₂O, M₂(S₂O₃)₂·xH₂O, M(S₂O₃)₃·xH₂O, M₃(S₂O₃)₄·xH₂O, M(S₂O₃)₅·xH₂O, and M₂(S₂O₃)₇·xH₂O, wherein x varies based on the nature of M;
dithionites, e.g., selected from M₂SO₄, MS₂O₄, M₂(S₂O₄)₃, M(S₂O₄)₂, M₂(S₂O₄)₂, M(S₂O₄)₃, M₃(S₂O₄)₄, M(S₂O₄)₅, and M₂(S₂O₄)₇;
dithionites hydrates, e.g., selected from M₂S₂O₄·xH₂O, MS₂O₄·xH₂O, M₂(S₂O₄)₃·xH₂O, M(S₂O₄)₂·xH₂O, M₂(S₂O₄)₂·xH₂O, M(S₂O₄)₃·xH₂O, M₃(S₂O₄)₄·xH₂O, M(S₂O₄)₅·xH₂O, and M₂(S₂O₄)₇·xH₂O, wherein x varies based on the nature of M;
phosphates, e.g., selected from M₃PO₄, M₃(PO₄)₂, MPO₄, and M₄(PO₄)₃;
phosphates hydrates, e.g., selected from M₃PO₄·xH₂O, M₃(PO₄)₂·xH₂O, MPO₄·xH₂O, and M₄(PO₄)₃·xH₂O, wherein x varies based on the nature of M;
Metal alkyls;
Metal alkoxides;
Metal amines;
Metal phosphines;
Metal thiolates;
Metal halides;
Combined cation-anion single source precursors, i.e., molecules that include both cation and anion atoms, for example of the formula M(E₂CNR₂)₂(M=Pb, Rb, E=S, P, Se, Te, OI, As, and R=alkyl, amine alkyl, silyl alkyl, phosphoryl alkyl, phosphyl alkyl).

In some embodiments, the metal precursor is a metal alkanoate as selected herein. In some embodiments, the metal alkanoate is a metal precursor of the metal atom forming the shell material, namely the wetting layer and the islands.

In some embodiments, the precursors may be added in the form of complexes and/or clusters.

In some embodiments, the process of the invention comprises treating core nanostructures, e.g., bare nanorods of at least one semiconductor material, with at least one precursor of the shell semiconductor material, the at least one precursor being at least one precursor of a metal, as selected herein and at least one precursor of a chalcogenide material, as defined, at a temperature between 100 and 400° C.

In some embodiments, the core is treated with a precursor material under conditions selected from:

1. a temperature between −25° C. to 500° C.; or a temperature between −20° C. to 500° C.; or a temperature between −10° C. to 500° C.; or a temperature between 0° C. to 500° C.; or a temperature between 10° C. to 500° C.; or a temperature between 50° C. to 500° C.; or a temperature between 100° C. to 500° C.; or a temperature between 150° C. to 500° C.; or a temperature between 200° C. to 500° C.; or a temperature between 250° C. to 500° C.; or a temperature between 300° C. to 500° C.; or a temperature between 350° C. to 500° C.; or a temperature between 400° C. to 500° C.; any one or more of the above embodiments and/or

2. a precursor concentration between 1 aM (attomolar, 10⁻¹⁸) and 10M; or between 1×10⁻¹⁷M and 10M; or between 1×10⁻¹⁶M and 10M; or between 1×10⁻¹⁵M and 10M; or between 1×10⁻¹⁴M and 10M; or between 1×10⁻¹³M and 10M; or between 1×10⁻¹²M and 10M; or between 1×10⁻¹¹M and 10M; or between 1×10⁻¹⁰M and 10M; or between 1×10⁻⁹M and 10M; or between 1×10⁻⁸M and 10M; or between 1×10⁻⁷M and 10M; or between 1×10⁻⁶M and 10M; or between 1×10⁻⁵M and 10M; or between 1×10⁻⁴M and 10M; or between 1×10⁻³M and 10M; or between 1×10⁻²M and 10M; or between 1×10⁻¹M and 10M; or between 1M and 10M; any one or more of the above embodiments and/or

3. the precursor material is introduced at a continuous mode or in quanta (multi additions), at a rate from 0.1 μL/hr per 1 mL, based on the initial volume of core nanostructure solution. In other words, for any 1 Liter of the initial volume, the addition rate varies, or gradually increases, from 0.1 mL/hr to 100 L/hr; any one or more of the above embodiments and/or

4. over a period of time resulting from a slow addition of the precursor material into the core material. The length of the addition period may depend on any of the above conditions. In some embodiments, the precursor is added over a period of time extending between several hours and several days.

The thickness of shell may be tuned by the amounts of added precursor solutions.

The invention further provides a core/islands-shell colloidal semiconductor nanostructure comprising a core nanostructure and a wetting layer on the circumference of the core nanostructure, the wetting layer being decorated with material islands.

As used herein, the material islands are material regions vertically grown on the second semiconductor material wetting layer that consist of the second semiconductor material and arranged as regions of excess material (3D structures), that are distinct and may be of any shape and size. These islands may be point islands or a collection of point islands, randomly or non-randomly distributed on the wetting layer. The islands may be spaced-apart or may be in contact with each other to form a continuous structure such as a line structure or a line pattern. The line structure or pattern or otherwise any continuous collection of the material islands may be arranged on any region of the wetting layer or may be formed helically on the wetting layer.

In some embodiments, the islands are helically arranged on the circumference of the core nanostructure. In some embodiments, the helical arrangement is of spaced apart islands or in the form of a continuous helical line pattern. The helical arrangement may be formed along the main axis of the nanostructure, or along any axis thereof and may be right handed or left handed, thus providing unique chiral systems.

In some embodiments, a population of helical nanostructures comprises a racemic combination of left handed and right handed helical nanostructures (ration of 1:1), or a combination wherein one or another of the helical nanostructures is preferred.

Thus, the invention further provides a chiral core/islands-shell colloidal semiconductor nanostructure comprising a core nanostructure and a wetting layer on the circumference of the core nanostructure, the wetting layer being chirally decorated with material islands. The nanostructure may thus be right-handed or left-handed.

The invention also provides a nanostructure of a first semiconductor material having a surface decoration in the form of a helical decoration of a second semiconductor material, the helical decoration may be right-handed or left-handed.

A nanostructure population is also provided that comprises a plurality of nanostructures, each nanostructure being of a first semiconductor material and having a surface decoration in the form of a helical decoration of a second semiconductor material, the helical decoration may be right handed or left handed; wherein the population may comprise the right-handed nanostructures, the left-handed nanostructures or a combination of both.

The nanostructures of the invention are unique systems that may be used in a variety of applications but not limited to, including photocatalysis, light induced radical polymerization, oxygen consumption applications, lasing, chromophores for display applications, linearly polarized emission, circularly polarized emission, catalyst for the synthesis of chiral organic molecules, photo-current generation, printed electronics applications and more.

### BRIEF DESCRIPTION OF FIGURES

FIGS 1A-B present TEM images of (A) CdSe nanorods with a CdS shell, (B) ZnS nanorods with a CdS shell. The results show that in comparison to SK growth on nanowires, the shell growth on the nanorod system did not proceed through SK growth. All scale bars are 25 nm.

FIGS. 2A-F present shape evolution of ZnSe/ZnS core/shell nanorods in the process of shell growth. (A) TEM image of bare ZnSe nanorods; (B-E) TEM images of ZnSe/ZnS nanorods by injecting 2.5 mL, 4.0 mL, 6.0 mL and 10.5 mL of ZnS precursors; Inset are the corresponding HRTEM images. (F) XRD of ZnSe nanorods (sample a), ZnSe/ZnS core/shell nanorods (sample c; sample e); the standard XRD patterns of bulk wurtzite ZnSe and ZnS are also shown for comparison. Scale bars in (A-E) are 25 nm; the scale bars in insets are 2 nm.

FIGS. 3A-C show histograms of diameter of original (A) ZnSe nanorods and (B, C) ZnSe/ZnS core/shell nanorods, corresponding to the samples as shown in FIG. 2A, 2B and 2C in the main text respectively.

FIGS. 4A-C present evolution of (A) absorption and (B) emission spectra in the synthesis of ZnSe/ZnS core/shell nanorods. Spectra 1-5 correspond to the samples as shown in FIGS. 1A-B, respectively. (C) Evolution of PL wavelength and PL QY as a function of the thickness of ZnS shell.

FIGS. 5A-B present (A) PLE photo-selection measurements and (B) corresponding fluorescence anisotropy of ZnSe/ZnS nanorods. The emission polarization of ZnSe/ZnS nanorods is measured by using the excitation photo-selection method. The ZnSe/ZnS nanorods are excited by a vertical light, followed by the measurements of photoluminescence excitation (PLE) spectra parallel (I_{VV}) and perpendicular (I_{VH}) to the excitation light.

FIG. 6 present shape evolution of ZnS shell growth on CdSe/CdS seeded nanorods (upper) and CdSe nanorods (bottom). All the scale bars are equal to 25 nm.

FIGS. 7A-D present histograms of diameter of (A) CdSe/CdS seeded nanorods, (B) CdSe/CdS/ZnS core/shell nanorods, (C) CdSe nanorods and (D) CdSe/ZnS nanorods, corresponding to the samples as shown in FIGS. 6A, 6B, 6D and 6E in the main text respectively.

FIG. 8 presents the effect of lattice mismatch on the thickness of wetting layer.

FIGS. 9A-C present the generality of three-dimensional islands growth in colloidal shell growth. (A) ZnSe growth on ZnS nanorods; (B) ZnSe growth on CdSe/CdS seeded nanorods; (C) ZnS growth on CdS nanoplates. The insets in (A) and (B) are corresponding HRTEM images; the inset in (C) is the corresponding SEM image. The scale bars in (A-C) are 25 nm; the scale bars in insets of (A-B) and (C) are 5 nm and 25 nm, respectively.

FIGS. 10A-E presents evolution of (A) absorption and (B) emission spectra in the synthesis of ZnSe shell growth on CdSe/CdS seeded nanorods as a function of the volume of ZnSe precursor solutions; (C) and (D) show the TEM images of nanorods after injecting 0.4 mL and 1.2 mL of ZnSe precursor solutions, respectively. The sample shown in FIG. 9B is obtained by injecting 2.0 mL of ZnSe precursor solutions. (E) XRD of CdSe/CdS seeded nanorods (black) and CdSe/CdS/ZnSe nanorods (the sample in FIG. 9B). The standard XRD patterns of bulk hexagonal CdS and hexagonal ZnSe are also shown for comparison. The scale bars in (C-D) are 25 nm; the scale bars in insets are 2 nm.

FIGS. 11A-B present TEM images with different magnifications of ZnS/ZnSe/CdS core/shell/shell nanorods, which are synthesized by growing CdS on dimensional ZnSe islands on ZnS nanorods in the sample shown in FIG. 9A.

FIGS. 12A-F present shape evolution of ZnSe/ZnS core/helical-islands nanorods in the process of shell growth by using a zinc precursor with controlled low reactivity. (A-E) TEM image of ZnSe/ZnS nanorods with increased amounts of ZnS precursors showing the core/helical-islands shell grown nanorods; (F) the corresponding HRTEM image of the sample in e. Scale bars in (A-E) are 20 nm.

FIGS. 13A-F present (A) ZnSe nanorods kept for a week in water under inert and aerobic conditions, showing the oxidation of the ZnSe in the presence of oxygen resulted in the loss of their absorption features and (B) their catalytic activity as photoinitiators for radical polymerization. (C) Incubation of ZnSe for 1 hr under dark conditions with DDAB also dampened their photo-initiation capacity. (D) Absorption spectra of ZnSe and ZnSe/ZnS NRs used for the stability and activity test. Insets: TEM image of the ZnSe/ZnS showing an SK growth features. (E,F) The ZnSe/ZnS nanocrystals showed similar conversion behavior before and after exposure to oxygen or DDAB.

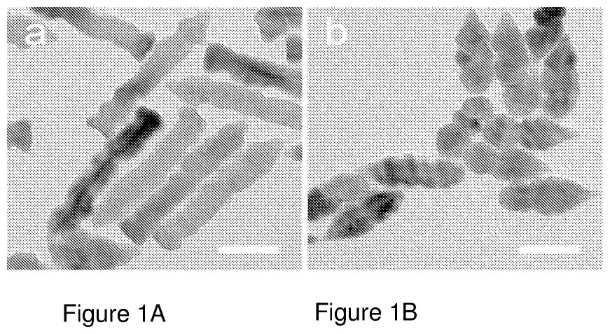

### DETAILED DESCRIPTION OF EMBODIMENTS

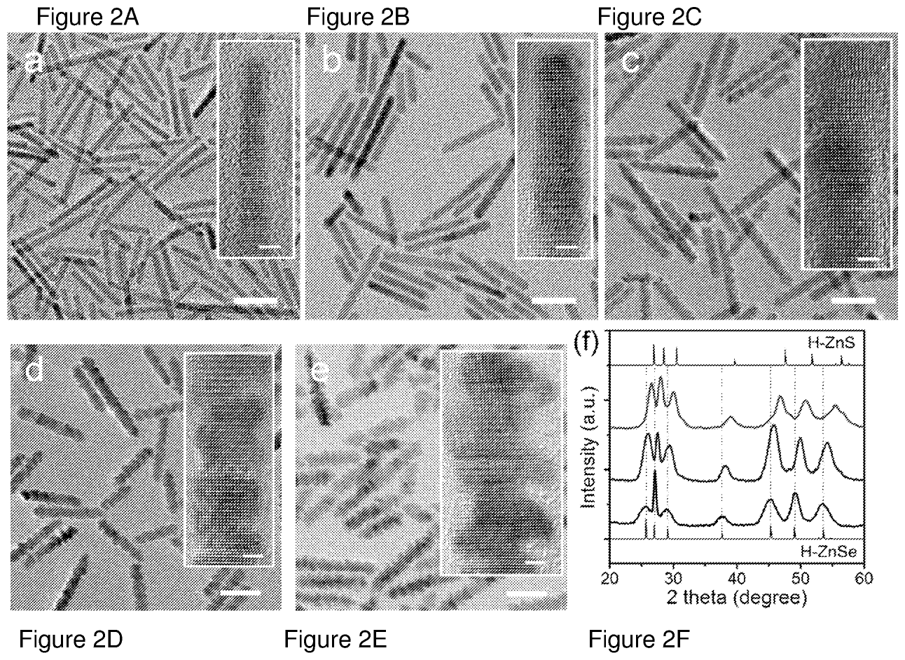

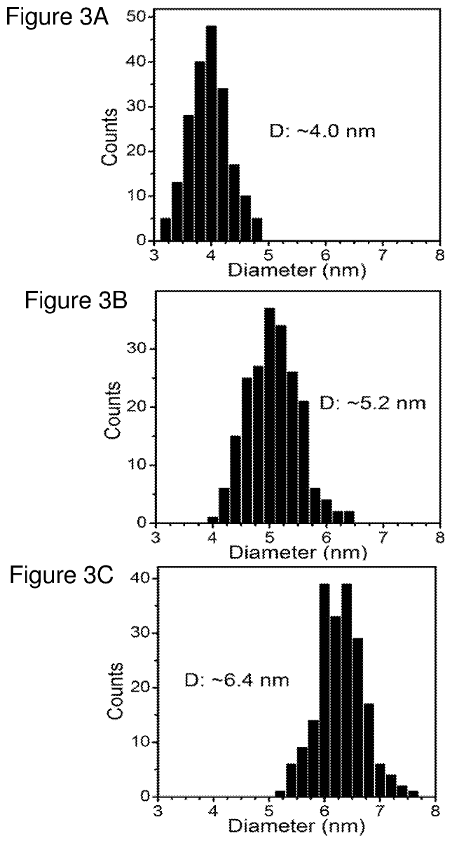

Colloidal growth of epitaxial shells on existing nanorods was illustrated in the synthesis of ZnSe/ZnS core/shell nanorods which possesses a typical type-I band alignment. First, ZnSe nanorods of ˜30 nm in length and ˜4.0 nm in diameter were synthesized via oriented attachment (FIG. 2A). HRTEM measurement shows that ZnSe nanorods are single-crystalline, with two planes being perpendicular to each other, a typical hexagonal wurtzite structure. Purified ZnSe nanorods were redispersed in a mixture of 1-octadecene (ODE), oleylamine (OLA) and oleic acid (OA).

Second, shell precursors with low reactivity (alkylthiol and metal oleate) were slowly introduced at elevated temperature to grow the shell on anisotropic nanocrystals. The thiol group can bond strongly to soft metal ions on the surface of the nanoparticles while the existence of metal oleate induces the cleavage of the strong carbon-sulfur valence bond in alkylthiol at high temperature. Specifically, the ZnS shell was grown by slowly injecting Zn oleate and 1-octanethiol separately at high temperature (310° C.). The thickness of ZnS shell can be tuned by the amounts of injected precursor solutions. Aliquots were taken to monitor the progress of the ZnS shell growth during the synthesis as a function of the volume of injected precursors. Thanks to the low reactivity of shell precursors, no significant self-nucleation was observed throughout the entire shell growth.

In comparison to similar syntheses for shell growth on QDs which resulted in the formation of a uniform thick shell, the slow introduction of precursors with low reactivity allowed to the achieve SK growth on anisotropic nanostructures.

As shown in FIG. 2B, initially a uniform ZnS shell was grown on ZnSe nanorods. The diameter of nanorods increased from ˜4.0 nm to ˜5.2 nm, corresponding to a shell thickness of 0.6 nm, about 2 monolayers of ZnS (the average thickness of one monolayer of wurtzite ZnS is ˜0.31 nm). HRTEM image shows the shell growth in an epitaxial way. As more shell precursors were injected, the diameter continuously increased to 6.4 nm, corresponding to 3.8 monolayers of ZnS (FIG. 2C). TEM image reveals that the surface of the obtained nanorods became slightly irregular and different contrasts were also visible along the rod, suggesting shell thickness inhomogeneities. Such inhomogeneities can be ascribed to the appearance of small bulges appeared on the surface of nanorods as manifested in the HRTEM image. Further injection of shell precursors produced thicker nanorods with increased roughness of the nanorod surface (FIG. 2D). HRTEM indicates that more ZnS islands grew on the sides along the length of the whole nanorod. Finally, zigzag ZnS shell was obtained as shown in FIG. 2E. Corresponding HRTEM image clearly shows the three-dimensional islands growth.

FIG. 2F presents the powder X-ray diffraction (XRD) data during the shell growth process. Powder X-ray diffraction (XRD) of bare ZnSe nanorods matches that of a wurtzite structure of ZnSe The relatively sharper (002) peak at ˜27° indicates the favorable growth along the c-axis. The ZnS shell growth shifted all the diffraction peaks to higher angles consistent with the smaller lattice constant for ZnS compared with ZnSe. The original wurtzite crystal structure was maintained, indicating epitaxial shell formation, which is a result of slow shell deposition.

The shell growth mode during the synthesis of ZnSe/ZnS nanorods as shown above is analogous to the Stranski-Krastanov (SK) growth mechanism, a typical growth mode in two-dimensional epitaxial film growth on a flat substrate using precursor deposition from the gas phase as applied in molecular beam epitaxy for growth of semiconductor quantum wells. In SK growth, when a second material is deposited on a substrate of a different material, first complete film (up to several monolayers) can be deposited layer-by-layer. The stain energy induced by the lattice mismatch between the two materials will increase as the layer thickness increases. Above a critical layer (wetting layer) thickness, three-dimensional island growth will be favored to relieve the misfit strain.

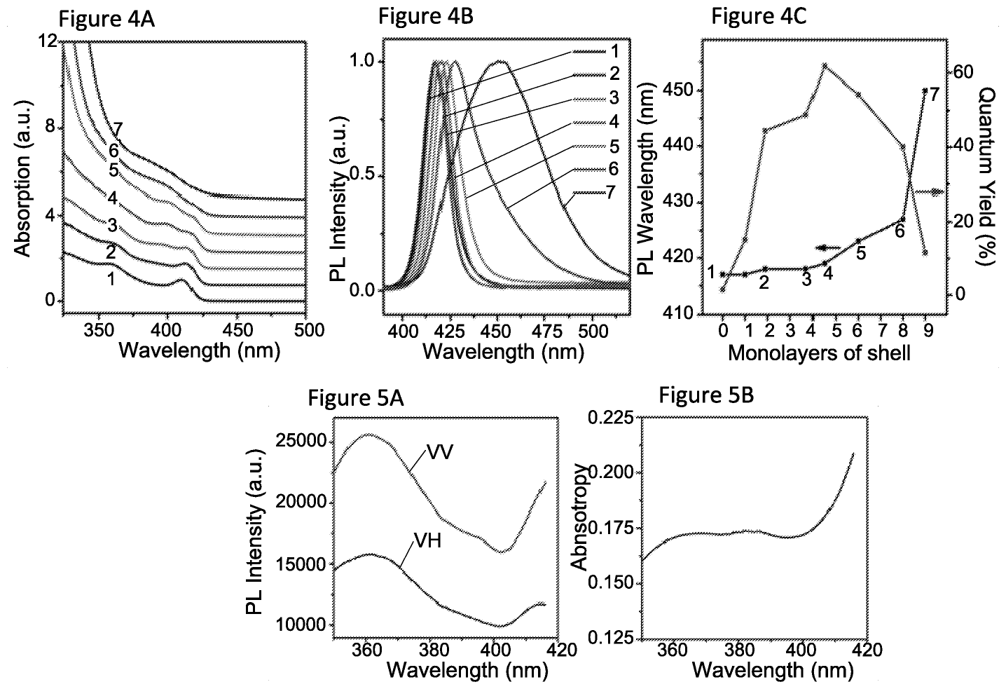

Absorption spectra were measured during ZnS shell growth process as a function of the volume of precursor solutions, as shown in FIG. 4A. The band gap of ZnS larger and straddles that of ZnSe (Type-I band alignment). The narrow absorption spectrum with resolved transitions indicates the uniform diameter of ZnSe nanorods. A slight red shift was observed on the absorption after a thin layer growth of ZnS In this process, the main shape of the absorption spectra was preserved. Further increase of the shell thickness broadened the excitonic transitions, which may be due to the shell thickness variations and the following islands growth. The gradually increased absorption cross section at energies higher than the ZnS band gap (3.54 eV, 350 nm) derived from the growth of the ZnS shell, since no significant self-nucleation of ZnS was observed.

Bulk ZnSe has a relatively large band gap of 2.7 eV (459 nm). Bare ZnSe nanorods with a diameter of 4.0 nm displayed a purple emission (421 nm) with a low quantum yield (˜1.5%), as shown in FIG. 4B and C. Initial ZnS growth induced a small red shift (˜1 nm) on the emission. As more ZnS shell was grown, the emission spectra remained almost unchanged. In this process, the corresponding fluorescence quantum yield increased steadily (FIG. 4C), showing an improving surface passivation. When the thickness of the ZnS shell was around 4 monolayers, the emission wavelength slowly started to shift to the red, during which the quantum yield (QY) reached ˜60%. As revealed by the corresponding TEM image (FIG. 2D) at this stage, the core/shell nanorods had the thickest shell when the islands growth starts. It should be noted that all the samples before this stage during the synthesis display a narrow photoluminescence peak with FWHM being smaller than 16 nm. The emission anisotropy of ZnSe/ZnS nanorods is also measured by using the excitation photo-selection method. The ZnSe/ZnS nanorods display a typical anisotropy between 0.15 and 0.2 in the measured wavelength range (FIG. 5), an exceptional value for colloidal nanoparticles that emit in the short wavelength range. Further ZnS shell growth slightly shifted the emission spectra to the red and decreased the quantum yield, indicating that the lattice strain induced by islands growth of ZnS start to introduce defects at the core/shell interface (5 in FIG. 4). The red shift can indicate the effects of strain. The defects increased significantly as more ZnS precursors were added, accompanied by a quick decrease of QY. During this process, a new trap emission around 460 nm emerged and became dominant as ZnS further grew (6 and 7 in FIG. 4).

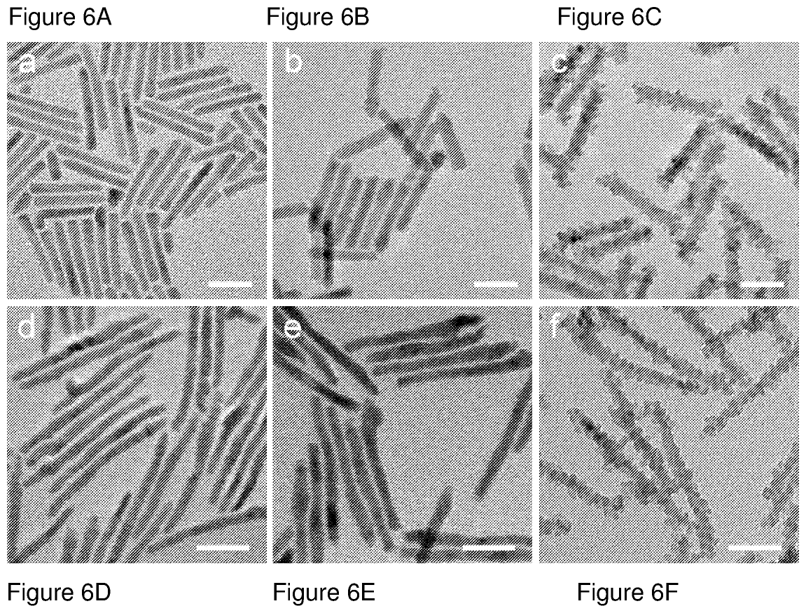

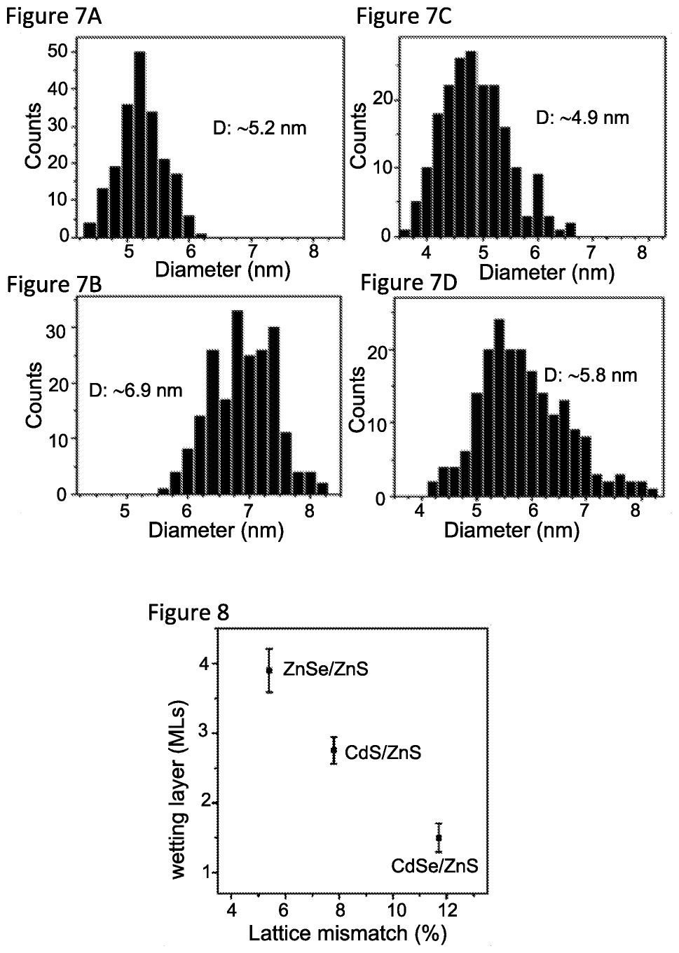

To expand the family of such unique rod/shell architectures and aiming to demonstrate the generality of this growth behavior of ZnS, ZnS shell growth was performed also on CdSe/CdS seeded nanorods and CdSe nanorods via the same method (FIG. 6). CdSe/CdS seeded nanorods with a length of ˜40 nm and a diameter of ˜5.2 nm were synthesized through a hot injection method. First, the injection of ZnS precursor solutions resulted in nanorods that remained monodisperse, as shown in FIG. 6B. The diameter of the obtained nanorods gradually increased to 6.9 nm, which corresponds to ˜3 monolayers of ZnS (FIG. 7). Three-dimensional ZnS islands emerged as more ZnS precursor solutions were injected (FIG. 6C). Similarly, ˜1.5 monolayers of ZnS shell were grown on CdSe nanorods (diameter, ˜4.9 nm) before the islands growth started (FIG. 6E). Further ZnS growth led to the islands formation on the surface of CdSe nanorods (FIG. 6F). It should be noted that the diameter of single CdSe nanorod was not uniform because of the presence of stacking faults in the growth process. For some long CdSe nanorods, the diameter at one side was even smaller than 4 nm. However, all three-dimensional islands growth appeared homogeneously along the whole nanorods (FIG. 6F), indicating the central role of lattice mismatch for SK growth.

For the epitaxial film growth on two-dimensional flat substrate, the misfit strain energy at the interface increases as the film thickens. For a specific film thickness, the stain energy is mainly determined by the lattice mismatch between the film and the substrate. In SK growth, three-dimensional island growth starts when the film thickness exceeds the thickness of the wetting layer. Thereby, a thinner wetting layer is expected for a bigger lattice mismatch between the film and the substrate. The lattice mismatch between hexagonal ZnS and hexagonal ZnSe, CdS and CdSe is ˜5.4%, 7.8% and 11.7% respectively. The thickness of the wetting layer of ZnSe/ZnS, CdS/ZnS and CdSe/ZnS core/shell nanorods are extracted from the above TEM analysis. As displayed in FIG. 8, the thickness of the wetting layer decreases with the increase of the lattice mismatch between the core nanorod and the shell, clearly showing the wetting layer thickness is inversely proportional to the lattice mismatch. This further establishes the unique SK growth mode on nanorods invented herein and offering principals for the design of such materials.

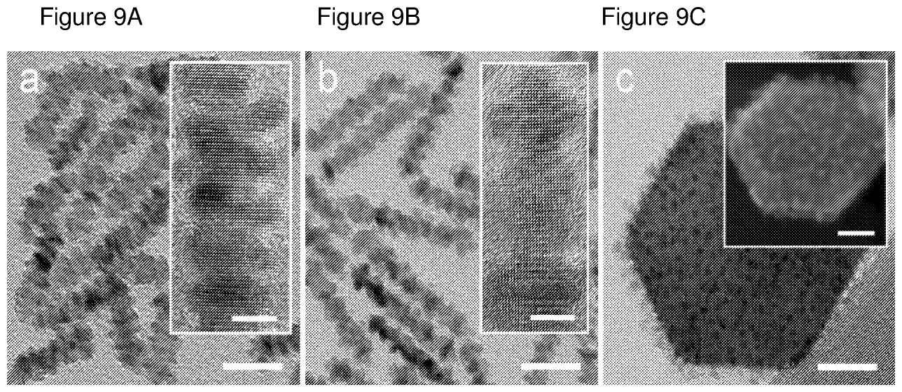

Three-dimensional island growth during the shell formation was further extended to different materials and morphologies (FIG. 9). Injection of selenium precursor (TOP-Se) to the solution of ZnS nanorods with zinc precursor (zinc oleate) at high temperature first increased the diameter of the nanorods, followed by the island growth on the surface of nanorods, as illustrated by the surface roughness and contrast variation (FIG. 9A). This result in an additional example of the unique architecture invented herein.

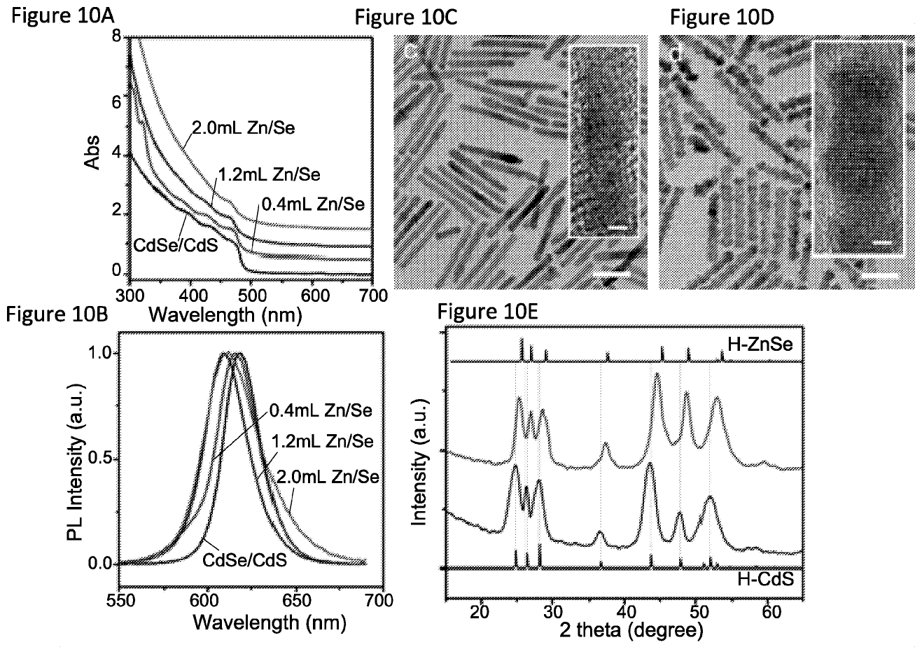

Analogous islands growth of ZnSe was observed on CdSe/CdS seeded nanorods under similar experimental conditions, as shown in FIG. 9B. The XRD of CdSe/CdS seeded nanorods matches that of the bulk wurtzite CdS because of small volume fraction of CdSe core in seeded nanorod. All the diffraction peaks shifted to higher angles upon the shell growth of ZnSe, during which the core/shell nanorods inherited the hexagonal wurtzite crystal structure of the core nanorods (FIG. 10). Hexagonal ZnSe and CdS have relatively small lattice mismatch (˜2.6%). At the synthesis temperature (300° C.), cation diffusion is suggested. The produced ZnS-CdSe interface provides the necessary lattice strain for islands growth. The ZnSe shell deposition shifted the emission of CdSe/CdS nanorods to short wavelength by ˜6 nm, which can be explained by some decrease of the CdS shell thickness due to the cation diffusion. In this process, interfacial defects can be formed, leading to the reduced emission intensity (FIG. 10).

The islands growth of ZnS on two-dimensional CdS nanoplates is also shown in FIG. 9C. Hexagonal CdS nanoplates were synthesized from Cu_{1.94}S nanoplates via cation exchange. Compared with the starting CdS nanoplate, a hairy shell with low contrast is observed upon the ZnS growth. Meanwhile, contrast variations can be distinguished in the center part. SEM image reveals the growth of isolated nanosized islands on hexagonal nanoplates (the inset in FIG. 9C).

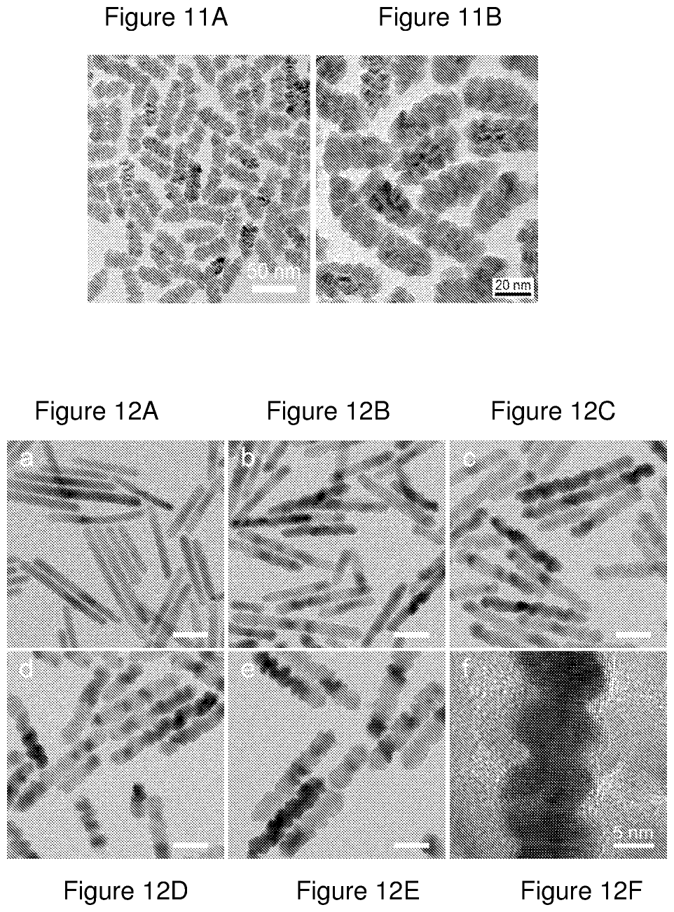

Injecting CdS precursors on ZnSe-islands-decorated ZnS nanorods (sample shown in FIG. 9A) led to CdS growth around ZnSe islands, producing a complex heteronanrods with larger islands (FIG. 11). This further proves the formation of three-dimensional ZnSe islands on ZnS nanorods in the sample shown in FIG. 9A.

The islands-shell growth was further controlled by controlling the growth rate approaching the thermodynamic limit. This may be achieved via controlling the precursor reactivity. Using excess of oleic acid can increase the solubility of metal oleate, leading to a lower reactivity. Thus the effect of excess of oleic acid was used to further control the islands-shell morphology by using zinc oleate with a mole ratio of 1:10 (Zn:oleic acid) instead of 1:6.3 during ZnS shell growth process. As shown in FIG. 12A, a uniform ZnS coverage was grown on ZnSe nanorods similar to the growth as shown in FIG. 2B. As more shell precursors were added, the appearance of small bulges made the surface of the obtained nanorods become unsmooth (FIG. 12B). However, the distance between the bulges is notably bigger than that shown in FIG. 2c and d. Further growth of ZnS shell induced the curvature on the surface of the obtained nanoparticles (FIG. 12C) ZnSe/ZnS nanorods with unique core/helical-islands morphology were obtained when adding more ZnS precursors (FIG. 12D). The helical shell became more emphasized after further growth of ZnS (FIG. 12E). The formation of unique core/helical-islands nanorods is considered as one special case of core/islands-shell growth. During the synthesis of core/helical-islands nanorods, the slower ZnS growth speed allows adequate time for the crystal orientation induced by the strain field, leading to the transformation from unordered islands to ordered helical islands to minimize the surface energy.

One non-limiting application for core/shell nanorods with SK growth is as photoinitiators for radical-polymerization. This application requires photochemical stable photoinitiators with the capacity to produce reactive species that could initiate the polymerization step upon light excitation. For the ZnSe/ZnS core/shell structure, the capacity to fulfill these two requirements is not-straightforward, since they are somewhat orthogonal, high stability could be gained by thick shell while charge transfer from the nanocrystal to molecules in solution for the production of reactive species requires a thin shell.

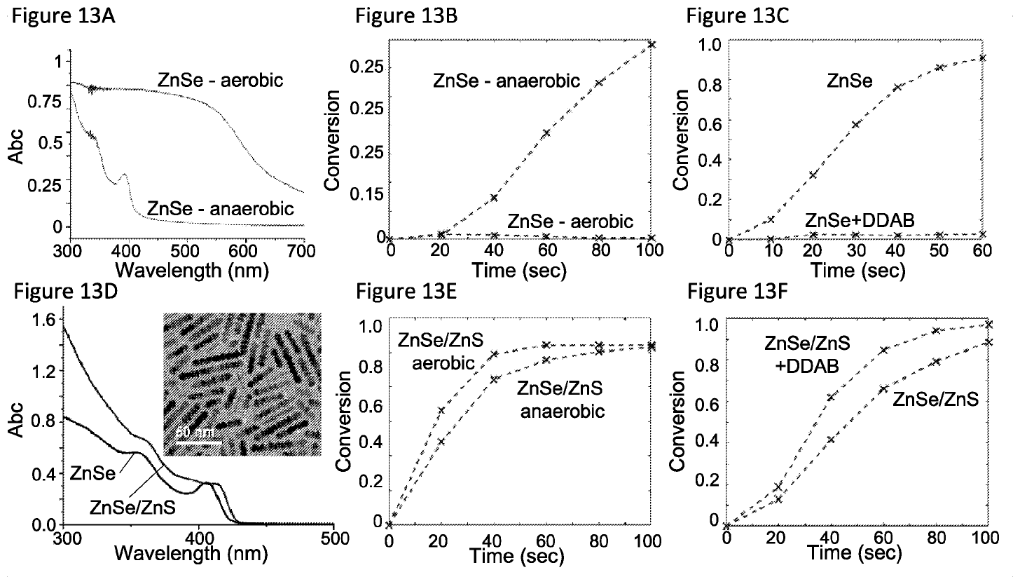

ZnSe nanorods were transferred to aqueous solution by phase transfer with polyethylenimine (PEI) and were kept under inert or aerobic conditions for several days. Nanorods oxidation was observed 24 hr after incubation in aerobic conditions, manifested in the solution becoming reddish, attributed to the formation of selenium oxyanions. Within a week all the ZnSe absorption features where eventually lost (FIG. 13A). In parallel the capacity of these nanocrystals to be used as photoinitiators for radical polymerization was examined by exciting them in the presence of acrylic monomer solution and detecting the concentration of unreacted monomers by FTIR. The results showed the oxidation of the nanoparticles also resulted in the loss of their photo-initiation activity (FIG. 13B) Similar loss in activity was seen also following 1 hr incubation of the ZnSe nanorods with DDAB a known etching agent (FIG. 13C).

The advantages of the unique structure invented herein are demonstrated next. Unlike the ZnSe nanorods, the ZnSe/ZnS system with SK growth (FIG. 13D) maintained its stability and high photo-initiation capability also in air. We did not observe any significant change in the absorption spectrum or the photo-polymerization activity following exposure to oxygen or DDAB, FIG. 13E and F, respectively. This clearly demonstrates the power of the SK growth providing photochemical stability while maintaining the photocatalytic activity of the nanocrystals.

### CONCLUSIONS

In summary, a new type of core/islands shell nanoparticles was developed along with the method of their preparation. As a prototypical example—the colloidal synthesis of ZnSe/ZnS core/islands shell nanorods was demonstrated. In the growth of these core/islands shell growth, the mechanism of ZnS growth occurs in an analogous manner to the established Stranski-Krastanov growth mechanism in the field of thin film epitaxial growth from the gas phase: first uniform shell coverage and then three-dimensional islands growth when beyond a critical shell thickness. The obtained unique ZnSe/ZnS core/islands-shell nanorods display some unique characteristics stemming from the architecture. A narrow emission in the short wavelength range and high emission anisotropy are detected. The ability to generalize this type of novel colloidal nanostructure to form a complete family of novel materials is further shown for other systems: First, when growing ZnS on CdSe/CdS seeded nanorods and on CdSe nanorods. Moreover—Core/islands-shell nanorods with larger lattice mismatch display a thinner wetting layer, indicating the critical thickness is inversely proportional to the lattice mismatch. This is a signature of the SK growth mechanism also in deposition from the gas phase on epitaxial films growth. Besides, unique core/helical-islands ZnSe/ZnS nanoparticles are obtained by decreasing the speed of the ZnS shell growth. In the growth of the core/helical-islands nanoparticles, first uniform shell coverage is obtained, followed by the formation of helical shell, resulting from ordering induced by the strain field to minimize the surface energy. This is the first report of helical shell growth on nanorods. The islands growth during the shell deposition is shown to be extended to different materials (ZnSe) and morphologies (two-dimensional nanoplate), thus forming a new family of novel colloidal nanostructures.

The capacity to utilize the power of the SK growth is also demonstrated to provide “opposing” properties such as photochemical stability along with photocatalytic activity. These studies not only manifest a general phenomenon in colloidal shell deposition on anisotropic nanostructures but also provide an approach to synthesize complex heterostructures with clear potential for chemical, biomedical and optoelectronic applications.

1. A nanostructure of a first semiconductor material having each of its dimensions in the nanoscale, the nanostructure being coated on its circumference with a Stranski-Krastanov (SK) type shell of a second semiconductor material, said layer of the second semiconductor material being decorated with a plurality of material islands at least a portion thereof being present at regions of lattice misfit strain, wherein the material islands are of the same second semiconductor material, and wherein the first and second semiconductor materials are different, the nanostructure being different from a nanowire or a quantum dot.

2. (canceled)

3. The nanostructure according to claim 1, wherein the layer of a second semiconductor material comprise one or more monolayers of said second semiconductor material.

4. The nanostructure according to claim 1, wherein the material islands are orderly arranged or randomly arranged.

5. The nanostructure according to claim 1, wherein the material islands are orderly arranged in a line form, optionally helically arranged on the layer coating the circumference of the nanostructure.

6. (canceled)

7. (canceled)

8. The nanostructure according to claim 1, being a nanostructure of a first semiconductor material, coated with a film comprised of one or more monolayers of a second semiconductor material, the film being characterized by regions of accumulated lattice strain, said regions exhibit three-dimensional islands of the second semiconductor material, wherein the first and second semiconductor materials are different.

9. (canceled)

10. (canceled)

11. The nanostructure according to claim 1, being in the form selected from nanorods, nanotubes, nanoparticles and nanoplates, excluding nanowires and quantum dots.

12. (canceled)

13. The nanostructure according to claim 11, being a nanorod.

14. (canceled)

15. (canceled)

16. The nanostructure according to claim 1, wherein the first and second semiconductor materials, independently, are selected from elements of Group I-VII, Group II-VI, Group III-V, Group IV-VI, Group III-VI, Group IV semiconductors, Group III-VI semiconductors, Group I-VI semiconductors, I-VII semiconductors, IV-VI semiconductors, V-VI semiconductors, II-V semiconductors and I-III-VI₂ semiconductors, or oxides, ternary semiconductors, quaternary semiconductors, and alloys and combinations thereof. cm 17-24. (canceled)

25. The nanostructure according to claim 1, being a core/island-shell nanostructure comprising Zn-based semiconductor materials.

26. (canceled)

27. (canceled)

28. A process for the manufacture of a nanostructure according to claim 1, the process comprising contacting core nanostructures with at least one shell precursor material having a low reactivity, at elevated temperatures.

29. The process according to claim 28, wherein the at least one shell precursor material is added at a rate and under thermal conditions permitting growth of a wetting layer and material islands on the surface of the shell-free nanostructures.

30. The process according to claim 28, wherein the thermal conditions comprise a temperature between −25° C. to 500° C.; or a temperature between −20° C. to 500° C.; or a temperature between −10° C. to 500° C.; or a temperature between 0° C. to 500° C.; or a temperature between 10° C. to 500° C.; or a temperature between 50° C. to 500° C.; or a temperature between 100° C. to 500° C.; or a temperature between 150° C. to 500° C.; or a temperature between 200° C. to 500° C.; or a temperature between 250° C. to 500° C.; or a temperature between 300° C. to 500° C.; or a temperature between 350° C. to 500° C.; or a temperature between 400° C. to 500° C.

31. The process according to claim 28, wherein the precursor concentration is between 1 aM (attomolar, 10⁻¹⁸) and 10M; or between 1×10⁻¹⁷M and 10M; or between 1×10⁻¹⁶M and 10M; or between 1×10⁻¹⁵M and 10M; or between 1×10⁻¹⁴M and 10M; or between 1×10⁻¹³M and 10M; or between 1×10⁻¹²M and 10M; or between 1×10⁻¹¹M and 10M; or between 1×10⁻¹⁰M and 10M; or between 1×10⁻⁹M and 10M; or between 1×10⁻⁸M and 10M; or between 1×10⁻⁷M and 10M; or between 1×10⁻⁶M and 10M; or between 1×10⁻⁵M and 10M; or between 1×10⁻⁴M and 10M; or between 1×10⁻³M and 10M; or between 1×10⁻²M and 10M; or between 1×10⁻¹M and 10M; or between 1M and 10M.

32. (canceled)

33. (canceled)

34. The process according to claim 28, wherein the at least one shell precursor material is selected from a chalcogenide precursor and a metal precursor.

35. (canceled)

36. (canceled)

37. (canceled)

38. The process according to claim 28, wherein the chalcogenide precursor is an alkyl thiol.

39-42. (canceled)

43. The nanostructure according to claim 1, being a core/islands-shell colloidal semiconductor nanostructure comprising a core nanostructure and a wetting layer on the circumference of the core nanostructure, the wetting layer being decorated with material islands.

44. The nanostructure according to claim 43, wherein the islands are helically arranged on the circumference of the core nanostructure.

45. The nanostructure according to claim 44, wherein the helical arrangement is right handed or left handed.

46. (canceled)

47. A nanostructure of a first semiconductor material having a surface decoration in the form of a helical decoration of a second semiconductor material, the helical decoration may be right-handed or left-handed.

48. A nanostructure population comprising a plurality of nanostructures, each nanostructure being of a first semiconductor material and having a surface decoration in the form of a helical decoration of a second semiconductor material, the helical decoration may be right handed or left handed; wherein the population may comprise the right-handed nanostructures, the left-handed nanostructures or a combination of both.

49-62. (canceled)
